(19) United States
(12) Patent Application Publication
(10) Pub. No.: US 2021/0273638 A1
(43) Pub. Date: Sep. 2, 2021

(54) UNIVERSAL SEMICONDUCTOR SWITCH

(71) Applicant: CENTUM ELECTRONICS LIMITED, Bangalore (IN)

(72) Inventors: Bhoopendrakumar Singh, Bangalore (IN); Vinod Chippalkatti, Bangaore (IN); Kanthimathinathan Thirugnanam, Bangalore (IN); Sukumar Patil, Bangalore (IN)

(21) Appl. No.: 17/322,854

(22) Filed: May 17, 2021

Related U.S. Application Data
(63) Continuation of application No. 16/475,144, filed on Jul. 1, 2019.

(51) Int. Cl. H03K 17/16; H03K 17/081; H03K 17/567; H03K 17/60; H03K 17/687

(52) U.S. Cl. CPC H03K 17/162; H03K 17/08104; H03K 17/687; H03K 17/60; H03K 17/567

(57) ABSTRACT

The present invention related to a universal semiconductor switch. In one embodiment, the switch includes a switching arrangement having an input power connection configured as input for a solid state switching device, the solid state switching device operationally coupled to a current limiting arrangement and an output circuit; the output circuit including a filter circuit. At least one trigger circuit including a power source and an on-and-off circuit, said trigger circuit operably coupled to the switching arrangement input power source and the solid state switching device. An on-command noise immunity circuit and an off-command noise immunity circuit are operationally coupled to the trigger circuit to suppress the noise from any external source, the switch will trigger only if the detected voltage is beyond the threshold voltage and for a predetermined duration.

### CROSS REFERENCE TO RELATED APPLICATION

This application is a continuation in pail of U.S. application Ser. No. 16/475,144, filed 1 Jul. 2019, the disclosure of which is incorporated, in its entirety, by this reference.

### FIELD OF INVENTION

The invention generally relates to the field of electronic switches and particularly to a universal semiconductor switch.

### BACKGROUND

An electronic switch is a device that can switch an electrical circuit, interrupting the current in the circuit or diverting the current from one conductor to another conductor. Examples of electronic switches include but are not limited to electromechanical relays and solid state relays. Electromechanical relays operate on the principle of a coil of wire that becomes a temporary magnet when electricity flows through the coil, which enables electromechanical relays to turn ON or OFF. One physical disadvantage of electromechanical relays is the relay being bulky and heavy. Other disadvantages of electromechanical relays include but are not limited to include high failure rate due to wearable parts, slower switching, generating electromagnetic noise and interference on power lines. Solid state relays are sensitive to corrosion, and oxidation. The Solid State Relay generates electromagnetic noise and interference on power lines and there is no noise immunity for the ON and OFF command signals. Other disadvantages are poor anti-interference ability, poor resistance to radiation, low reliability, and reverse leakage current. Yet another system known in the art provides a solid state power controller for switching power on and off to an electrical load. The controller limits the load current to a selected maximum level by controlling the drain-source resistance of power metal-oxide-semiconductor field-effect transistor (MOSFET) used for switching the power. The disadvantages of the controller include power loss in the MOSFET, which in turn leads to the failure of the controller and complex circuitry. The circuit is not capable of limiting the input plug-in inrush current by controlling the gate to source voltage of MOSFET. The loss in the MOSFET is high. The prevention for false triggering of the circuit is not possible.

Therefore, there is a need for a universal semiconductor switch that can be adapted for various modes of operation without the need to replace the switch.

### BRIEF DESCRIPTION OF DRAWINGS

So that the manner in which the recited features of the invention can be understood in detail, some of the embodiments are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of a universal semiconductor switch, according to an embodiment of the invention.

FIG. 2 shows a general circuit layout of the components of the universal semiconductor switch, according to an embodiment of the invention.

FIG. 2A shows a circuit layout of a subset of components in Isolated Non-Latch Switch with Plug-in in-Rush Current mode.

FIG. 2B shows a circuit layout of a subset of components in Isolated Non Latch Switch without Plug-in in-Rush Current mode.

FIG. 2C shows a circuit layout of a subset of components in Isolated Latch Type Switch without Plug-in in-Rush Current Limiting and Noise Immunity mode.

FIG. 2D shows a circuit layout of a subset of components in Isolated Latch Type Switch without Noise Immunity mode.

FIG. 2E shows a circuit layout of a subset of components in Non-Isolated Latch Switch with Plug-in in-Rush Current Limiting and Noise Immunity mode.

FIG. 2F shows a circuit layout of a subset of components in Non-Isolated Latch Switch without Plug-in in-Rush Current Limiting and Noise Immunity mode.

FIG. 2G shows a circuit layout of a subset of components in Non-Isolated Non-Latch Type with Plug-in in-Rush Current Limiting and Noise Immunity mode.

FIG. 2H shows a circuit layout of a subset of components in Non-Isolated Non-Latch Type without Plug-in in-Rush Current Limiting and Noise Immunity mode.

### SUMMARY OF THE INVENTION

One aspect of the invention provides a universal semiconductor switch. The universal semiconductor switch includes a switching arrangement having an input and an output. A trigger circuit is operably coupled to the switching arrangement. A noise immunity circuit is coupled to the trigger circuit.

### DETAILED DESCRIPTION OF THE INVENTION

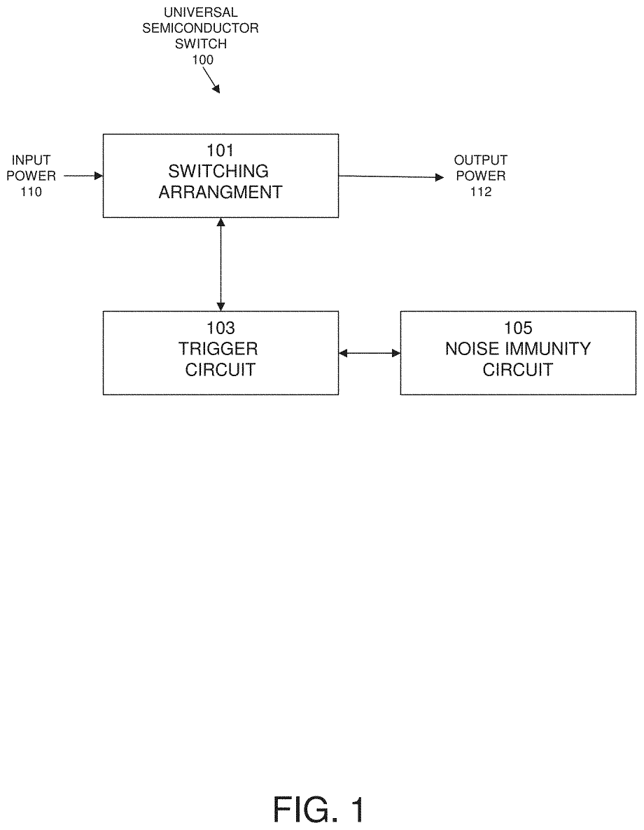

Various embodiments of the invention provide a universal semiconductor switch. FIG. 1 shows a block diagram of a universal semiconductor switch 100, according to an embodiment of the invention. The universal semiconductor switch includes a switching arrangement 101 having an input power 110 and an output power 112, a trigger circuit 103, and a noise immunity circuit 105. The switching arrangement 101 is operationally coupled to the trigger circuit 103 and the noise immunity circuit 105 is operationally coupled to the trigger circuit 103. The switching arrangement 101 switches the input power 110. The trigger circuit 103 is used to trigger the switching arrangement 101. The noise immunity circuit 105 is used to filter out unwanted signals in the trigger circuit 103.

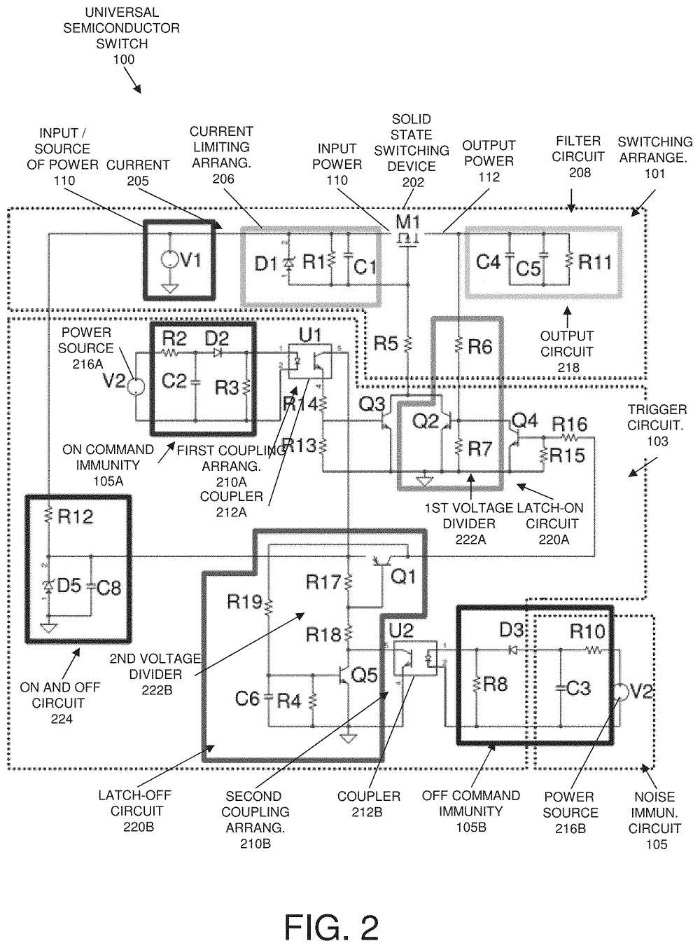

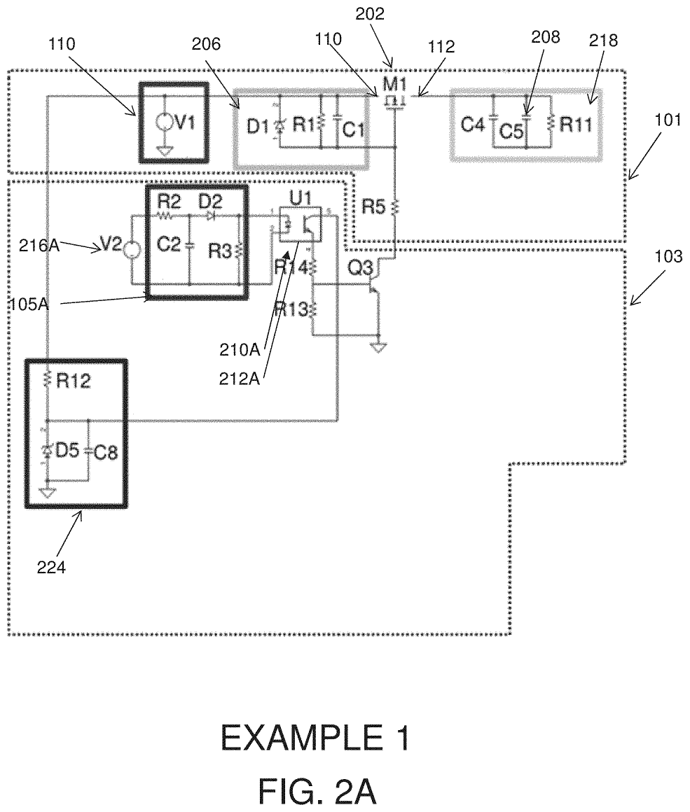

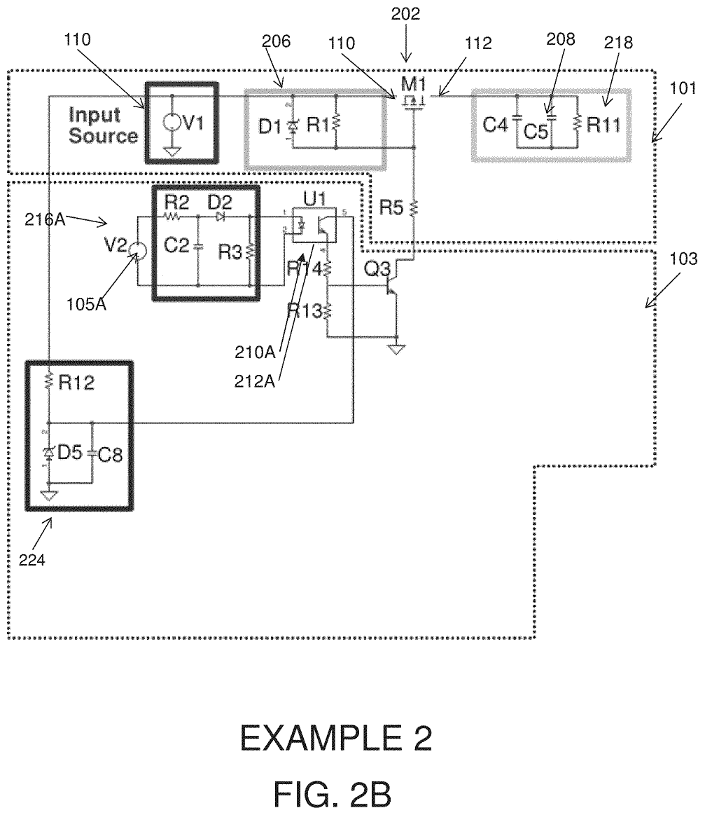

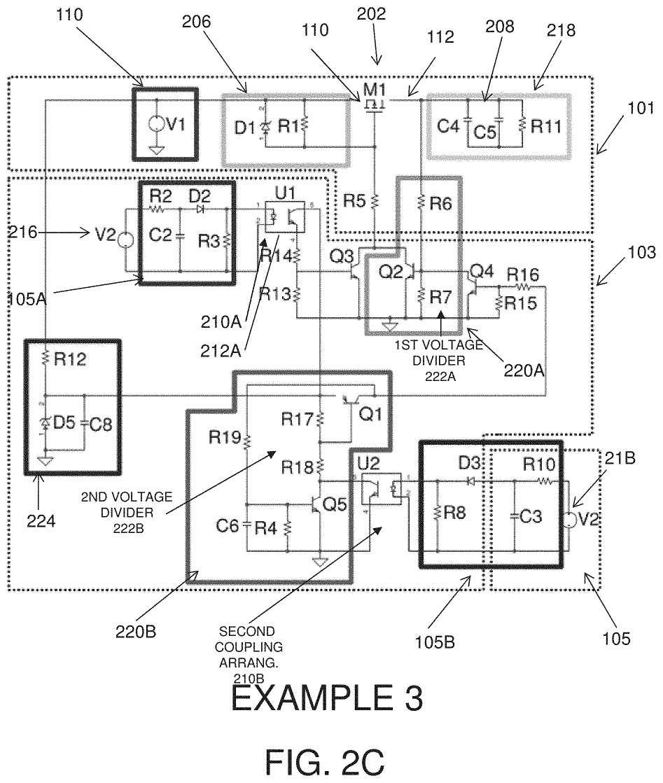

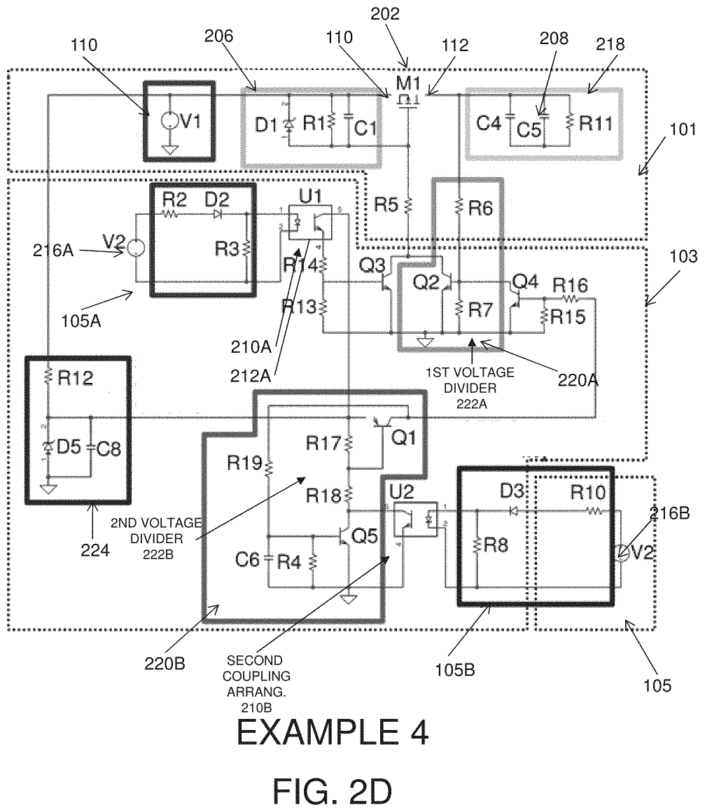

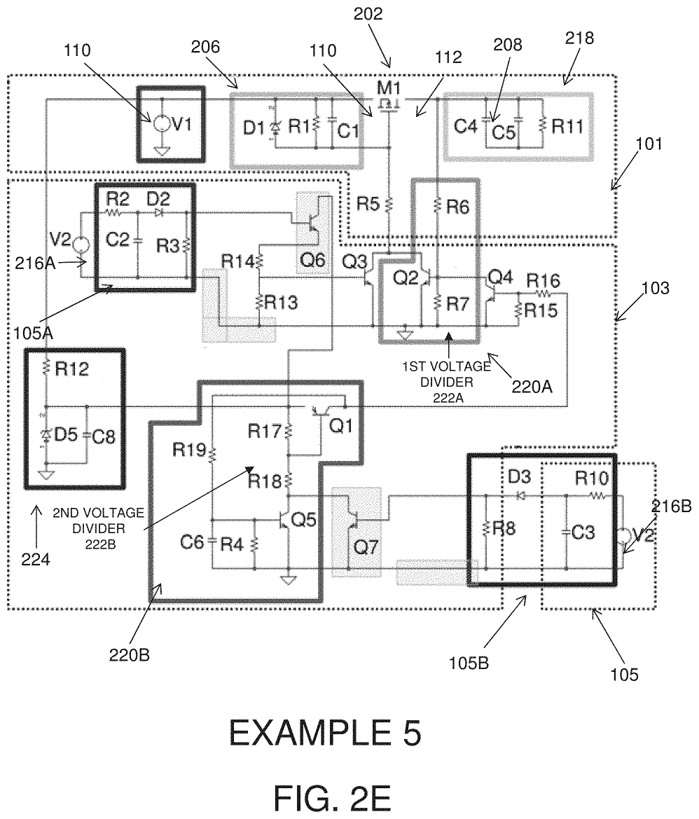

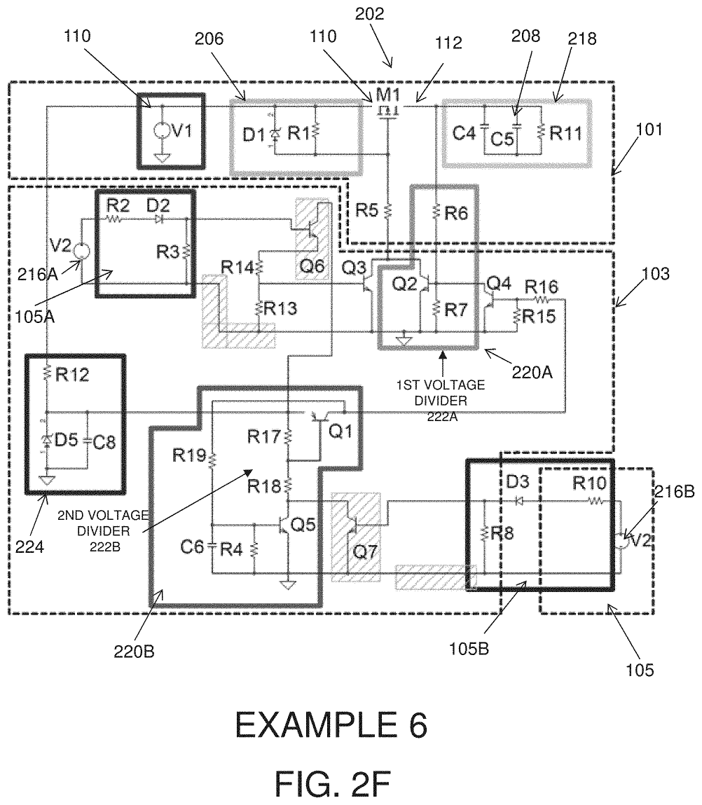

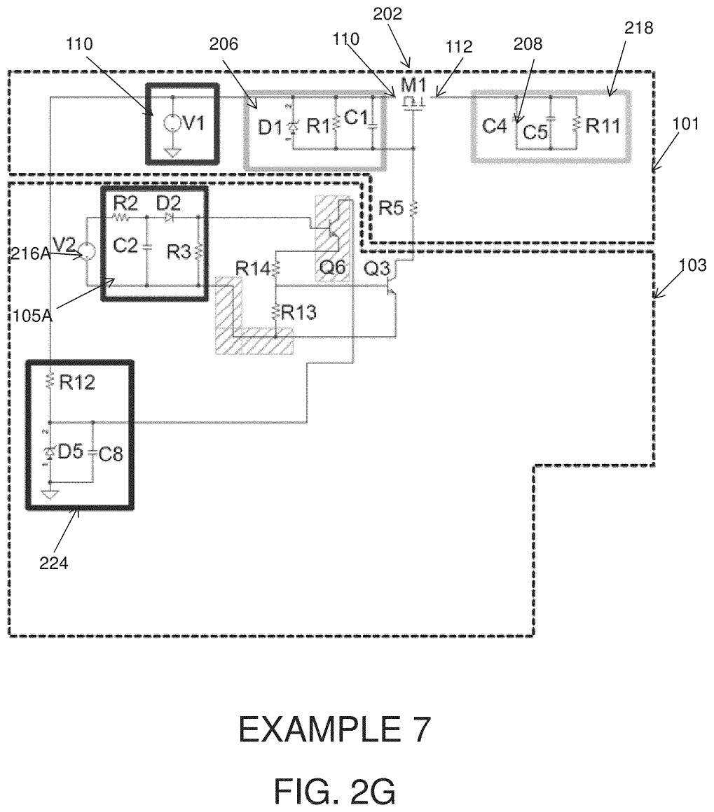

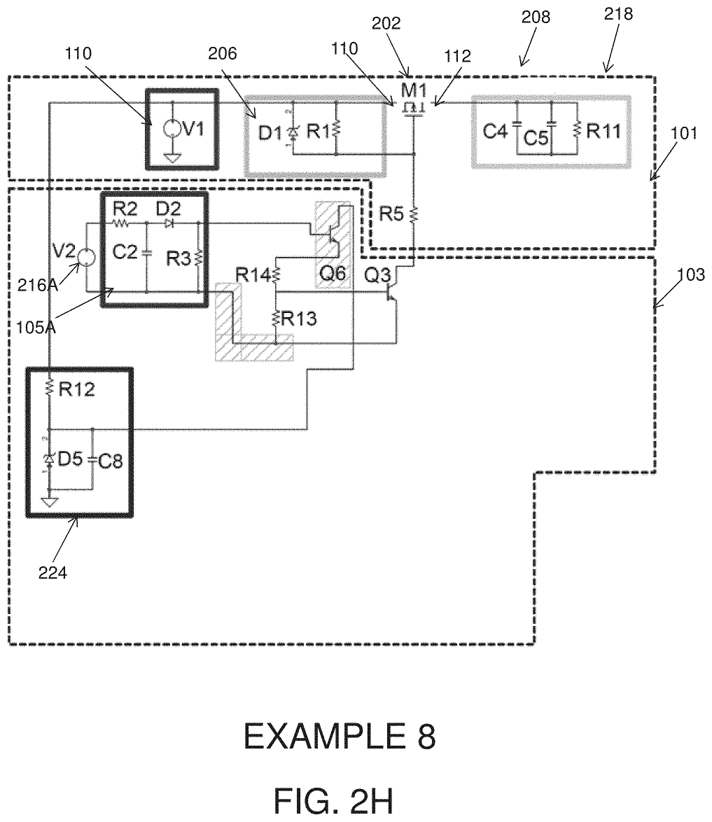

FIG. 2 shows a circuit layout of components of the universal semiconductor switch 100, according to an embodiment of the invention. The universal semiconductor switch 100 includes the switching arrangement 101. The switching arrangement 101 includes a solid state switching device 202. The solid state switching device 202 described herein includes but is not limited to MOSFET, BJT (bipolar junction transistor). IGBT (insulated-gate bipolar transistor), and/or combinations thereof. In one exemplary implementation, the switching is through a MOSFET M1. The solid state switching device 202 is connected to a source of power, the input power 110. The input power 110 is configured as the input for switching the solid state switching device 202. The solid state switching device 202 is turned ON by application of an ON command from the trigger circuit 103. A source voltage from the input power 110 is delivered to an output circuit 218 during the turn on of the solid state switching device 202. The output power 112 is the voltage across the output circuit 218. The solid state switching device 202 is operably coupled to a current limiting arrangement 206. The current limiting arrangement 206 limits current to the load.

The current limiting arrangement 206 includes but is not limited to passive circuit elements. A circuit passive element is an electrical component that does not generate power, but instead dissipates, stores, and/or releases power. Examples of passive circuit elements include but are not limited to NTC (negative temperature coefficient thermistor), resistors, capacitors, and/or combinations thereof. In an exemplary embodiment, the current limiting arrangement 206 is a combination of resistors and a capacitor. The current limiting arrangement 206 includes resistors R1 and R5, a capacitor C1 and a Zener diode D1. The combination of the R1, R5 and C1 provides soft start during the turn ON of the solid state switching device 202. The Zener diode D1 limits a gate-source voltage of the solid state switching device 202. The solid state switching device 202 is connected to the output circuit 218. The output circuit 218 includes a filter circuit 208 and a load resistor R11. Exemplary implementations of the filter circuit 208 include but are not limited to a capacitor filter, a LC filter, a RC filter and/or combinations thereof. In an exemplary embodiment, the filter circuit is a capacitor filter. The exemplary filter circuit 208 includes parallel connected capacitors C4 and C5 for filtering the source voltage of the input power 110 for the load resistor R11. The trigger circuit 103 is connected to the switching arrangement 101. The trigger circuit 103 includes an ON and OFF circuit 224. The ON and OFF circuit 224 supplies an ON command voltage and an OFF command voltage. The ON and OFF circuit 224 is powered by low voltage supply derived from the input power 110 using resistor R12 and Zener diode D5. Capacitor C8 provides filtering for the supply.

The trigger circuit 103 includes various coupling arrangements 210 (shown as 210A and 210B). The first coupling arrangement 210A includes a first coupler 212A. Further, the first coupling arrangement 210A can include isolated components or non-isolated components. Examples of isolated components include but are not limited to a transistor opto-isolator, a diode opto-isolator, a resistive opto-isolator, and/or combinations thereof. Examples of non-isolated components include but are not limited to a transistor, BJT, MOSFET, IGBT and/or combinations thereof.

Similarly, the trigger circuit 103 includes second coupling arrangement 210B that includes a second coupler 212B.

In one exemplary embodiment, the coupling arrangements 210 includes optocouplers U1 and U2. The function of optocouplers U1 and U2 is to provide isolation between ON/OFF command signal and control circuits.

The second coupling arrangement 210B is operationally connected to the noise immunity circuit 105. Examples of implementations of the noise immunity circuit 105 include, but are not limited to a low pass filter, a band pass filter, a band select filter and/or combinations thereof. In an exemplary embodiment, the noise immunity circuit 105 includes a low pass filter.

Power sources V2 can be connected at various locations in the universal semiconductor switch 100, shown as power source 216A and power source 216B. The power sources V2 are connected to the coupling arrangements 210. Examples of power sources 216 include, but are not limited to a pulse generator, pulsating power sources, signal generators, pulse timers, digital pulse signals and/or combination thereof. The power source 216B is connected to the second coupling arrangement 210B through the noise immunity circuit 105. The power source 216A is connected to the first coupling arrangement 210A through a on command immunity circuit 105A.

The noise immunity circuit 105 includes an on command immunity circuit 105A (also referred to in this document as “on command circuit”) and an off command immunity circuit 105B (also referred to in this document as “off command circuit”). Note, for clarity, the on command immunity circuit 105A is shown in the trigger circuit 103. In the ON command immunity circuit 105A, the power source V2 (216A) is shown as the ON command pulse. The ON command pulse can be a pulse voltage of limited duration or a DC voltage. When the ON Command Voltage is applied, R2-C2 circuit acts a low pass noise filter. Hence, if any noise voltage with duration less than a time constant of R2-C2 appears as the ON command, the circuit does not turn ON. Diode D2 helps in reverse voltage protection for ON command circuit. The resistor R3 is added to prevent unwanted turn ON of the opto-coupler U1 due to leakage current. Also, resistor R3 act as divider network with R2 to ensure the minimum voltage amplitude which is needed for turn ON of circuit. This circuit provides immunity against noise voltage of lower duration and lower voltage amplitude for turn ON circuit.

When ON command voltage of recommended amplitude and duration greater than the R2-C2 time constant is applied at the power source 216A, the capacitor C2 is charged and the diode D2 and input photo diode of U1 are conducting. Hence, the optocoupler U1 is turned ON and voltage is applied from collector of U1 to emitter of U1 and this voltage signal turns ON transistor Q3. Therefore, the bottom part of resistor R5 is pulled down to ground resulting in turn ON of the MOSFET switch M1. The MOSFET M1 is turned ON slowly to limit the inrush current from the input power 110. The inrush current can be adjusted using a R1-C1-R5 time constant. If the time constant of R1-C1-R5 is high, MOSFET M1 is turned on slower resulting in lower inrush current. Here, the MOSFET is made to work in the active region during the turn on (dissipation occurs in M1). Once the soft start period is over, the MOSFET M1 works in saturation mode and loss in the MOSFET M1 is reduced.

In the off command immunity circuit 105B, the power source V2 216B is shown as the OFF-command pulse. This can be a pulse voltage of limited duration or a DC voltage. When the OFF-Command Voltage is applied, the R10-C3 circuit acts a low pass noise filter. Hence, if any noise voltage with duration less than the time constant of the R10-C3 circuit appears as the OFF command, the circuit does not turn OFF. Diode D3 helps in reverse voltage protection for OFF command circuit. The resistor R8 is added to prevent unwanted turn OFF of the optocoupler U2 due to leakage current. Also, resistor R8 act as divider network with R10 to ensure the minimum voltage amplitude which is needed for turn OFF of circuit. This circuit provides immunity against noise voltage of lower duration and lower voltage amplitude for turn OFF circuit.

When OFF command voltage of recommended amplitude and duration greater than the R10-C3 time constant is applied, the capacitor C3 is charged and the diode D3 and the input photo diode of U2 are conducting. Hence, the optocoupler U2 is turned ON and voltage is applied from collector of U2 to emitter of U2 and this voltage signal pulls down lower side of the resistor R18 to ground resulting in turn OFF of the MOSFET switch M1.

The trigger circuit 103 includes latch arrangements 220. The latch arrangements include voltage divider 222. Examples of voltage divider 222 include but are not limited to a resistive voltage divider network, a capacitive voltage divider network and/or combinations thereof. In one non-limiting example, the voltage divider 222 is a resistive voltage divider. The voltage divider network is connected to a plurality of semiconductor switching components such as transistors Q2, Q3, Q4, Q1, and Q5. Examples of semiconductor switching components include but are not limited to a transistor, a MOSFET, a BJT, an IGBT, and/or combinations thereof. In a non-limiting example, the plurality of semiconductor switching components are transistors. The latch arrangements 220 also includes a plurality of passive components. Examples of passive components are described above, and include but are not limited to a resistor, a capacitor, and/or combinations thereof. In a non-limiting example, the passive components are at least one combination of the resistor and the capacitor.

The latch arrangements 220 include a latch-on circuit 220A and a latch-off circuit 220B. In the latch-on circuit, once the solid state switching device 202 is turned on, the output voltage from output circuit 218 forces resistor R6 to conduct, thereby turning on transistor Q2. The turn ON of Q2 forces the solid state switching device 202 to work in latch ON condition. This means the solid state switching device 202 continues to be in ON state even if the on-command voltage is removed. The circuit continues to be in the ON mode until the off command is applied or the input voltage V1 (the input power 110) is reduced below the threshold voltage. A first voltage divider 222A includes series connected resistors R6 and R7. The first voltage divider 222A determines the designed input threshold voltage where the universal semiconductor switch 100 circuit will be turned ON when input voltage is reduced. Also, the resistor R7 provides immunity for the transistor Q2 against leakage currents, which can cause unwanted turn ON of Q2.

In the latch-off circuit 220B, when resistor R18 is pulled to ground resistors R17-R18 acts as a second voltage divider 222B thereby turning ON transistor Q1. Hence, supply voltage is available at transistor Q1 collector. This voltage turns ON transistor Q4 through resistor R16. When transistor Q4 is turned ON, the base voltage of transistor Q2 is pulled down resulting in turn OFF of the transistor Q2. This in turn turns OFF the MOSFET M1 and hence transistor Q2 will come out from latched ON mode. The universal semiconductor switch 100 circuit is off until ON command is applied again. The function of resistor R15 is to prevent unwanted turn ON of Q2 due to leakage current. The collector voltage of Q1 forces transistor Q5 to turn ON through R19. Once Q5 is turned ON, it will continue to turn ON transistor Q1 in latch mode. Both Q1 & Q5 are ON continuously and forces the circuit to work in OFF mode till ON command is applied again.

### Working of the Circuit:

In an exemplary embodiment, the universal switch 100 as is operated by providing the input power 110 to the source terminal of the MOSFET M1. The trigger circuits 103 are selectively powered. In one example, one of the trigger circuits is powered ON and the other trigger circuit is powered OFF. The selective triggering of the trigger circuit enables the MOSFET M1 to start turning ON. The turning ON of the MOSFET M1 yields an output power 112 across the filter circuit 208. The turning ON of the MOSFET M1 of the switching arrangement 101 further activates the current limiting arrangement 206. The current limiting arrangement 206 is configured for restricting a current 205 from the input power 110 (V1), limiting the current 205 to a pre-determined value. During a first turning on of the solid state switching device 202 (M1), M1 draws maximal instantaneous input current from the input power 110. This maximal instantaneous input current is called “in-rush current” 205. The value of the in-rush current of the current 205 is dependent on the operating conditions of the universal semiconductor switch 100.

The universal semiconductor switch 100 can be configured to perform in a plurality of modes. In one example embodiment the switch is to suppress the noise from any external source, the switch will trigger only if the detected voltage is beyond the threshold voltage and for a predetermined duration. The switch further includes a latch-on circuit coupled via the first coupling arrangement to the power source in order to provide a continuous output even though the input command voltage goes off. Further, the switch further includes a latch-off circuit configured for keeping the power off even the input voltage is present in the circuit, even after the off command signal goes away.

Examples of mode of performance include at least one of an isolated non latch switch, an isolated latch switch, a non-isolated latch switch or a non-isolated non latch switch. Examples of the modes of performance are explained, below.

### Example 1: Isolated Non-Latch Switch with Plug-in In-Rush Current

FIG. 2A shows a circuit layout of a subset of components configured in Isolated Non-Latch Switch with Plug-in in-Rush Current mode. The isolated non-latch switch with plug-in in-rush current mode configuration is achieved by selectively operating the latch arrangement of the trigger circuit. The non-latch mode is derived by excluding the voltage divider 222 of the latch arrangement 220. The exclusion of the voltage divider 222 turns OFF the latch arrangement 220. The turning OFF of the latch arrangement 220 of the trigger circuit 103 enables operation of the universal semiconductor switch 100 through the trigger circuit 103 as shown in the current figure. However, the output from output circuit 218 of the universal semiconductor switch 100 is unaltered by the non-latch condition. Further, the signal (such as the current 205) delivered to M1 in the non-latch mode of the universal switch can be filtered through the noise immunity circuit 105.

The current example can be implemented by removing R6. R7 & Q2 from the general circuit layout (FIG. 2). R6, R7 & Q2 forms the latch-on circuit 220A for ON command. When ON command is applied (the power source 216A) for a particular duration, the R2-C2 portion of the ON command immunity circuit 105A gets charged and turns ON the U1 optocoupler. This in turn turns ON the transistor Q3 and hence the MOSFET M1 will turn ON. When ON command is removed (removing power from the power source 216A), the U1 optocoupler and the transistor Q3 will turn off, thereby turning OFF the MOSFET M1. Here OFF command circuit (the power source 216B and the off command immunity circuit 105B) is not necessary as there is no latching circuit in ON command. The ON command circuit itself works like ON & OFF circuit. The moment ON command is removed, the circuit is turned OFF.

### Example 2: Isolated Non Latch Switch without Plug-in In-Rush Current

FIG. 2B shows a circuit layout of a subset of components configured in Isolated Non Latch Switch without Plug-in in-Rush Current mode. The non-latch mode of the switch is obtained in a manner as explained in the above example 1. Further, the exclusion of the current limiting arrangement 206 does not limit the input current from the input power 110 to a pre-determined value. Further, the input current delivered to the MOSFET M1 in the non-latch mode of the universal switch can be filtered through the on command immunity circuit 105A.

The current example can be implemented by removing the capacitor C1 from the general circuit layout (FIG. 2). When capacitor C1 is removed, the MOSFET M1 turn ON time will be very fast, as there is no soft start time. Hence the MOSFET M1 will not limit the inrush current during turn ON.

### Example 3: Isolated Latch Type Switch without Plug-in In-Rush Current Limiting and with Noise Immunity

FIG. 2C shows a circuit layout of a subset of components configured in Isolated Latch Type Switch without Plug-in in-Rush Current Limiting and Noise Immunity mode. The isolated latch switch without plug-in in rush mode configuration is achieved by operating the latch arrangements 220 (both the latch-on circuit 220A and the latch-off circuit 220B) of the trigger circuit 103 without the current limiting arrangement 206. The latch mode is derived by including the voltage dividers 222 of the latch arrangements 220. The inclusion of the voltage dividers 222 turns ON the latch arrangements 220. However, the output of the universal semiconductor switch 100 is unaltered by the latch condition. Further, the signal delivered to the MOSFET M1 in the non-latch mode of the universal switch can be filtered through the noise immunity circuit 105.

The current example can be implemented by removing the capacitor C1 from the general circuit layout (FIG. 2). Here all other features are included like isolation (using U1 and U2), latch & noise immunity. When the capacitor C1 is removed, the MOSFET M1 turn ON time will be very fast as there is no soft start time. Hence the MOSFET M1 will not limit the inrush current during turn ON.

### Example 4: Isolated Latch Type Switch without Noise Immunity

FIG. 2D shows a circuit layout of a subset of components configured in Isolated Latch Type Switch without Noise Immunity mode. The isolated latch switch with plug-in in rush mode configuration is achieved by operating the latch arrangement 220 of the trigger circuit 103 without the noise immunity circuit 105. The operation of the universal semiconductor switch 100 in the latch mode is as described herein above.

The current example can be implemented by removing the capacitor C2 (removes the noise immunity in ON command immunity circuit 105A) and the capacitor C3 (removes the noise immunity in OFF command immunity circuit 105B) from the general circuit layout (FIG. 2). When these capacitors (C2, C3) are removed, the charging time during ON/OFF command will become zero. Hence the current circuit will turn ON immediately after applying ON command. Similarly, when OFF command is applied, the circuit will turn OFF immediately after applying OFF command. The circuit will turn ON & OFF, even if a very narrow duration pulse is applied.

### Example 5: Non-Isolated Latch Switch with Plug-in In-Rush Current Limiting and Noise Immunity

FIG. 2E shows a circuit layout of a subset of components configured in Non-Isolated Latch Switch with Plug-in in-Rush Current Limiting and Noise Immunity mode. The non-isolated latch switch with plug-in in rush mode configuration is achieved by selecting a non-isolated transistor in the coupling arrangements 210 of the latch arrangement 220 of the trigger circuit 103. Further, the universal semiconductor switch 100 is operated with the noise immunity circuit 105 and the current limiting arrangement 206. The operation of the universal semiconductor switch 100 in the latch mode with the noise immunity circuit and the current limiting arrangement is as described herein above.

The current example can be implemented by replacing opto-couplers U1 and U2 by simple NPN (negative-positive-negative) transistors from the general circuit layout (FIG. 2). In this case, isolation between ON & OFF commands with respect to universal semiconductor switch 100 is lost. The grounds of ON & OFF command circuit (ground of V2) have to be shorted with switching circuit ground(ground of V1).

### Example 6: Non-Isolated Latch Switch without Plug-in In-Rush Current Limiting and Noise Immunity

FIG. 2F shows a circuit layout of a subset of components configured in Non-Isolated Latch Switch without Plug-in in-Rush Current Limiting and Noise Immunity mode. The non-isolated latch switch without plug-in in-rush mode configuration is achieved by operating the latch arrangement 220 of the trigger circuit 103 with the noise immunity circuit 105. The operation of the universal semiconductor switch 100 in the latch mode is as described herein above.

The current example can be implemented by removing capacitors C1. C2, and C3 from FIG. 2E. FIG. 2E shows non isolated circuit where plug in in rush current limiting feature is present. When the capacitor C1 is removed, the turn ON time of the MOSFET M1 will be very fast as there is no soft start time. Hence the MOSFET M1 will not limit the inrush current during turn ON. When the capacitors C2 and C3 are removed, the charging time during ON/OFF command will become zero. Hence, the circuit will turn ON immediately after applying ON command. Similarly, when OFF command is applied, the circuit will turn OFF immediately after applying OFF command. The circuit will turn ON & OFF, even if a very narrow duration pulse is applied.

### Example 7: Non-Isolated Non-Latch Type with Plug-in In-Rush Current Limiting and Noise Immunity

FIG. 2G shows a circuit layout of a subset of components configured in Non-Isolated Non-Latch Type with Plug-in in-Rush Current Limiting and Noise Immunity mode. The non-isolated latch switch with plug-in in-rush current limiting and noise immunity mode configuration is achieved by operating the latch arrangement 220 of the trigger circuit 103 with the noise immunity circuit (ON command immunity circuit 105A). The operation of the universal semiconductor switch 100 in the latch mode is as described herein above.

The current example can be implemented by replacing the opto-couplers U1 and U2 from the circuit of FIG. 2A with simple NPN transistors. The circuit of FIG. 2A does not have latching circuits. When the opto-couplers U1 and U2 are replaced by NPN transistors, the isolation between ON & OFF commands with respect to the universal semiconductor switch 100 will be lost. The grounds of ON & OFF command circuit (ground of V2) have to be shorted with switching circuit ground(ground of V1).

### Example 8: Non-Isolated Non-Latch Type without Plug-in In-Rush Current Limiting and with Noise Immunity

FIG. 2H shows a circuit layout of a subset of components configured in Non-Isolated Non-Latch Type without Plug-in in-Rush Current Limiting and Noise Immunity mode. The non-isolated non-latch switch without plug-in in-rush current limiting and with noise immunity mode configuration is achieved by operating the latch-off circuit 220B of the trigger circuit 103 with the noise immunity circuit (ON command immunity circuit 105A). The operation of the universal semiconductor switch 100 in the latch mode is as described herein above.

The current example can be implemented by removing the capacitor C1 from the circuit of FIG. 2G. The FIG. 2G circuit is non isolated non latch type circuit. When C1 is removed from the circuit of Example 7, the plug in in rush current function also will be removed.

Embodiments of the invention provide a universal semiconductor switch 100 that operates in various modes. The semiconductor switch 100 as described herein and as illustrated through the accompanying drawings can be used to switch DC voltage signals.

The foregoing description has been set merely to illustrate the invention and is not intended to be limiting. Since modifications of the disclosed embodiments incorporating the spirit and substance of the invention may occur to person skilled in the art, the invention should be construed to include everything within the scope of the appended claims and equivalents thereof.

What is claimed is:

1. A universal semiconductor switch comprising:
a switching arrangement including:
an input power connection configured as input for a solid state switching device, the solid state switching device being operationally coupled to a current limiting arrangement and an output circuit; the output circuit including a filter circuit;
at least one trigger circuit that includes a power source and an on-and-off circuit, said trigger circuit being operably coupled to the input power connection of the switching arrangement and the solid state switching device; and
an on-command noise immunity circuit and an off-command noise immunity circuit operationally coupled to the trigger circuit to suppress signal noise from external sources, the trigger circuit only triggering if a detected voltage is beyond a threshold voltage and for a predetermined duration.

2. The universal semiconductor switch of claim 1, wherein the universal semiconductor switch is configured to perform as at least one of an isolated non latch switch, an isolated latch switch, a non-isolated latch switch or an non isolated non latch switch.

3. The universal semiconductor switch of claim 1, wherein the solid state switching device is selected from the group comprising of at least one of a MOSFET, a BJT, an IGBT, and/or combinations thereof.

4. The universal semiconductor switch of claim 1, wherein the current limiting arrangement is selected from the group comprising of at least one of a resistor, a capacitor, and/or combinations thereof.

5. The universal semiconductor switch of claim 1, wherein at least one coupling arrangement provides isolation of the on-and-off circuit, the at least one coupling arrangement being implemented at least in part using a device selected from the group consisting of: a transistor opto-isolator, a diode opto-isolator, a resistive opto-isolator, an opto-isolated SCR, an opto-isolated triac, a transistor, a triac, a BJT, a MOSFET, a IGBT and/or combinations thereof.

6. The universal semiconductor switch of claim 1, wherein the on-command noise immunity circuit is selected from a group consisting of: a low pass filter, a band pass filter, a band select filter and/or combinations thereof.

7. The universal semiconductor switch of claim 1, wherein the trigger circuit further comprises:
a latch-on circuit; and
a first coupling arrangement of the at least one coupling arrangement;
the latch-on circuit being coupled via the first coupling arrangement to the power source in order to provide a continuous output even in the absence of an input command voltage.

8. The universal semiconductor switch of claim 7 wherein the latch-on circuit is implemented using a resistor divider coupled to a transistor.

9. The universal semiconductor switch of claim 7, wherein the latch-on circuit includes:
a first voltage divider network operationally connected to the output circuit;
a plurality of semiconductor switching components operationally connected to the first voltage divider network; and
a plurality of passive components operationally connected to the first voltage divider network.

10. The universal semiconductor switch of claim 9, wherein the first voltage divider network is of at least one voltage divider network, the at least one voltage divider network selected from the group consisting of: a resistive voltage divider network, a capacitive voltage divider network, and/or combinations thereof.

11. The universal semiconductor switch of claim 9, wherein the plurality of semiconductor switching components are selected from the group consisting of a transistor, a MOSFET, a BJT, an IGBT and/or combinations thereof.

12. The universal semiconductor switch of claim 9, wherein the plurality of passive components are selected from the group consisting of a resistor, a capacitor, a diode and/or combinations thereof.

13. The universal semiconductor switch of claim 1, wherein the on-command noise immunity circuit is selected from the group consisting of: a capacitor filter, an inductor filter, a LC filter, an RC filter and/or combinations thereof.

14. The universal semiconductor switch of claim 1, wherein the trigger circuit further comprising:
a latch-off circuit; and
a second coupling arrangement of the at least one coupling arrangement;
the latch-off circuit being coupled via the second coupling arrangement to an off-command noise immunity circuit that keeps the power off even if an on command voltage is present, even after an off command signal goes away.
